(19) United States
(12) Patent Application Publication
(10) Pub. No.: US 2012/0024333 A1
(43) Pub. Date: Feb. 2, 2012

(54) THERMOELECTRIC MATERIAL DEFORMED BY CRYOGENIC IMPACT AND METHOD OF PREPARING THE SAME

(75) Inventors: Sang-mock LEE, Yongin-si (KR); Kyu-hyoung LEE, Yongin-si (KR); Sung-ho JIN, San Diego, CA (US)

(73) Assignees: THE REGENTS OF THE UNIVERSITY OF CALIFORNIA, Oakland, CA (US); SAMSUNG ELECTRONICS CO., LTD., Suwon-si (KR)

(21) Appl. No.: 13/193,949

(22) Filed: Jul. 29, 2011

Related U.S. Application Data
(60) Provisional application No. 61/368,716, filed on Jul. 29, 2010.

(30) Foreign Application Priority Data
Jun. 24, 2011 (KR) 10-2011-0061789

(51) Int. Cl. H01L 35/28; H01B 1/04; C01B 33/02; B29C 35/16; C01B 19/00; C01B 33/06; C01B 31/36; H01B 1/02; C01B 19/04

(52) U.S. Cl. 136/205; 252/512; 252/516; 252/519.13; 252/519.1; 423/348; 423/509; 423/508; 423/344; 423/291; 264/28

(57) ABSTRACT

A thermoelectric material has a microstructure deformed by cryogenic impact. When the cryogenic impact is applied to the thermoelectric material, defects are induced in the thermoelectric material, and such defects increase phonon scattering, which results in enhanced figure of merit.

### CROSS-REFERENCE TO RELATED APPLICATIONS

This application claims priority to U.S. Provisional Patent Application No. 61/368,716, filed on Jul. 29, 2010, in the U.S. Patent and Trademark Office, and to Korean Patent Application No. 10-2011-0061789, filed on Jun. 24, 2011 in the Korean Intellectual Property Office, and all the benefits accruing therefrom under 35 U.S.C. §119, the contents of which in their entirety are herein incorporated by reference.

### BACKGROUND

1. Field

The present disclosure relates to thermoelectric materials that are deformed by cryogenic impact, thereby having enhanced defect density and methods of preparing the same.

2. Description of the Related Art

Studies on thermoelectric materials and devices have been actively conducted in recent years because of their desirable characteristics such as efficient solid state cooling and power generation. Bulk thermoelectric materials are generally considered not to have very high efficiencies for energy conversion or energy transport applications. With the advent of nanotechnology and materials fabrication tools, however, artificially fabricated quantum confined structures, such as quantum wells, are capable of exhibiting greatly enhanced efficiency for converting thermal energy to electrical energy. In recent years, studies on these structures have shown a steadily increasing figure of merit ZT (detailed in the Equation <1> below).

As a factor of measuring the performance of these thermoelectric materials, a non-dimensional figure of merit, i.e., a ZT value, represented by Equation 1 below is used:

$$ZT = \frac{{S}^{2} σ T}{k} \qquad 〈 Equation 1 〉$$

wherein S is the Seebeck Coefficient (in Volts/degree K), σ is the electrical conductivity (in 1/Ω-meter), T refers to absolute temperature in degrees Kelvin (K), and k is the thermal conductivity (in Watt/meter-degree K).

The Seebeck Coefficient S depends on the density of states (“DOS”). For reduced dimensions, for example, in two-dimensional quantum wells or one-dimensional nanowires, the DOS becomes much higher than the 3-dimensional bulk materials. The higher DOS thus leads to higher S and higher σ. The thermal conductivity k becomes smaller if the dimension involved is less than the phonon wavelength.

Improved thermoelectric materials with a ZT value of >1 result in various applications such as heat recovery and space power applications, and thermoelectric materials with a ZT value of >3 can be used in broader technology applications including power generators and heat pumps. In addition, reducing the size of particles constituting thermoelectric materials enables commonly-used bulk thermoelectric devices to have a greatly enhanced efficiency.

### SUMMARY

Provided are thermoelectric materials with a new structure.

Provided are methods of preparing the thermoelectric materials with the new structure.

Provided are devices that include the thermoelectric materials with the new structure.

Additional aspects will be set forth in part in the description which follows and, in part, will be apparent from the description, or may be learned by practice of the presented embodiments.

According to an aspect of the present invention, a thermoelectric material has a microstructure, which is deformed by cryogenic impact.

According to another aspect of the present invention, a method of preparing a thermoelectric material includes: preparing thermoelectric material powder, introducing the thermoelectric material powder into a metal or plastic jacket, and packing and sealing the metal or plastic jacket; and applying cryogenic impact to the metal or plastic jacket including the thermoelectric material powder to deform a microstructure of the thermoelectric material powder.

According to another aspect of the present invention, a thermoelectric device, a thermoelectric module, and a thermoelectric apparatus, which includes the thermoelectric material with the new structure.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIGS. 1 and 2 are diagrams illustrating single-axis deformation and cryogenic impact;

FIG. 3 is a diagram illustrating cryogenic impact;

FIG. 4 is a perspective view of an exemplary thermoelectric module;

FIG. 5 is a schematic diagram illustrating thermoelectric cooling using the Peltier effect of a thermoelectric module; and

FIG. 6 is a schematic diagram illustrating thermoelectric power generating by the Seebeck effect of a thermoelectric module.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

According to an embodiment, there is provided a thermoelectric material having a microstructure that is deformed by impact at cryogenic temperatures (hereinafter termed “cryogenic impact”).

When an impact is applied to thermoelectric material powder in a low temperature environment, the microstructure of the thermoelectric material is deformed, thereby causing defects in the microstructure. An increase in such defect density in the microstructure of the thermoelectric material contributes to the adjustment of the size of the microstructure. Thus, the number of sites where phonon scattering occurs may be increased. As a result, the movement of phonons, which transfer heat, is blocked and the movement of carriers is not interrupted, and thus the thermal conductivity k of the thermoelectric material may become much smaller. Accordingly, the figure of merit ZT is enhanced.

The thermoelectric material powder may have a particle size of nanometers or micrometers. For example, the thermoelectric material powder may have an average particle size of from about 1 nm to about 1,000 nm, and may have a particle size of from about 1 μm to about 1,000 μm. The average particle size is a number average particle size and is determined by determining the radius of gyration of the particles.

When the thermoelectric material is deformed by cryogenic impact, defects are generated in the thermoelectric material, including dislocations, twins, point defects, distorted grain boundaries, and distorted lattice structures. The degree of such defect formation increases as the strain rate is increased. Typical strain rate for cold rolling, swaging or extrusion is slower than 0.1 inch/inch/sec. Manual sledge hammer hitting provides a strain rate of 1 inch/inch/sec. Thus, further increased strain rate induces greater defects in the thermoelectric material. As a result, phonon scattering is more generated, and thus the thermal conductivity of the thermoelectric material is reduced.

The strain rate may be at least greater than or equal to about 5 inch/inch/sec, for example, in the range of about 50 inch/inch/sec to about 2,000 inch/inch/sec. For example, a device providing such high strain rate may be gas-driven gun or explosive-charge-driven gun. The gas-driven gun may be used in Hopkinson Bar Impact deformation.

The impact deformation may be performed at a cryogenic temperature, for example, at below about 0° C., at below about −50° C., or at a temperature in the range of about −150° C. to about −270° C. For example, the temperature of liquid nitrogen, i.e., about −196° C. may be used as the cryogenic temperature. Within this range of temperature, a greater number of defects may be induced in the microstructure of the thermoelectric material powder. On the other hand, the microstructure of the thermoelectric material powder may be broken at room temperature or higher.

The degree of the defect generated by cryogenic impact in the thermoelectric material may be defined by defect density, which refers to defects generated per unit volume, that is, by “defect area/unit volume (mm²/1 mm³).” In addition, the degree of the defect may be measured by observing the microstructure of the thermoelectric material powder. In the cryogenic impact deformation, the defect density may be at least about 2 times greater than that before the cryogenic impact deformation, for example, in the range of about 5 times to about 20 times the defect density prior to the cryogenic impact.

The thermoelectric material may be subjected to single-axis deformation prior to the cryogenic impact deformation. The single-axis deformation may be performed at a temperature in the range of about 100° C. to about 600° C. Particles of the thermoelectric material are elongated in one direction (single-axis deformation) by rolling, swaging, pultrusion or extrusion, and thus the thermoelectric material may have an anisotropic microstructure.

The thermoelectric material powder may have a more-linear structure as a result of the single-axis deformation. As a result, the density of state increases, and the Seebeck Coefficient S and the electrical conductivity a become much higher due to the further increased density of state. In addition, if the dimension involved is less than the phonon wavelength, the thermal conductivity k becomes smaller (i.e., it is reduced from thermal conductivity k of an isotropic powder).

The thermoelectric material may be at least one selected from the group consisting of a transition metal, a rare earth element, a Group II element, a Group XIII element, a Group XIV element, a Group XV element, and a Group XVI element. For example, the thermoelectric material may be at least one selected from the group consisting of Si, Bi—Sb—Te, Bi—Te—Se, Bi—Sb, Mg—Si, Mg—Ge, Mg—Sn, Pb—Sb—Ag—Te, B—C, Bi—Te, Co—Sb, Pb—Te, Ge—Tb, Si—Ge, Sb—Te, Sm—Co, and transition metal silicides. For example, the thermoelectric material may be at least one selected from the group consisting of Si, Si₁₋ₓGeₓ where 0<x<1, Bi₂Te₃, Sb₂Te₃, BiₓSb₂₋ₓTe₃ where 0<x<2, Bi₂TeₓSe₃₋ₓ where 0<x<3, B₄C/B₉C, BiSb alloy, PbTe, Mg—Si, Mg—Ge, Mg—Sn or ternary systems, binary/tertiary/quaternary skutterudites, and Pb—Sb—Ag—Te.

The thermoelectric material powder may have nano-sized particles, and may have an average particle size in the range of about 1 nm to about 1,000 nm. As noted above, the average particle size is determined by the radius of gyration and is a number average particle size.

The deformation process of the thermoelectric material will now be described with reference to the drawings.

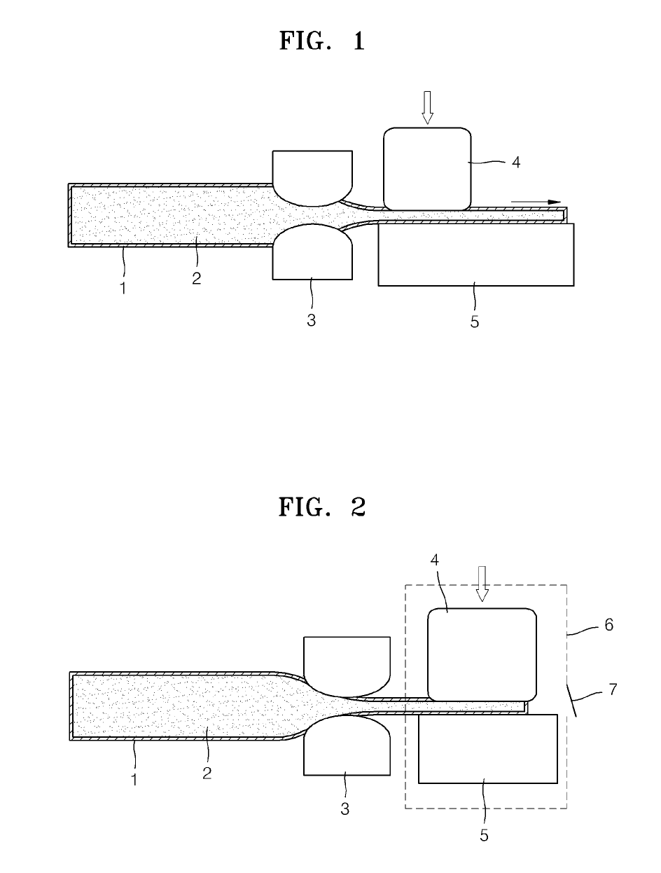

As illustrated in FIG. 1, thermoelectric material powder 2 is prepared, introduced into a jacket 1, and then packed and sealed. Subsequently, cryogenic impact 4 is applied to a portion of the jacket 1 including the thermoelectric material powder 2 that is mounted on a support 5 to deform the microstructure of the thermoelectric material powder 2, thereby inducing defects in the microstructure thereof.

When the thermoelectric material powder 2 is packed in the jacket 2, pores and empty space are decreased, and thus the figure of merit ZT may increase. Therefore, high-intensity packing is possible.

The jacket 1 may be formed of metal or plastic, and the metal may be copper, stainless steel, or high temperature alloys. The jacket 1 may be shaped into a desired dimension, and, for example, may be in the form of a casket. Such shaping also makes the thermoelectric material powder to be anisotropically elongated or deformed.

The cryogenic impact applied to the jacket 1 is performed at a strain rate of about 5 inch/inch/sec or higher, for example, in the range of about 50 inch/inch/sec to about 2,000 inch/inch/sec, and this enables an increase in the amount of nano-sized defects generated in the thermoelectric material.

The defects generated by cryogenic impact increases phonon scattering and reduces the thermal conductivity, which results in an enhanced figure of merit ZT.

The cryogenic impact may be performed at below about 0° C., for example, at below about −50° C., and, for example, at a temperature in the range of about −150° C. to about −270° C. Appropriately shaped defects are induced in the thermoelectric material within this range of temperature. Liquid nitrogen may be used for the low temperature environment.

The low temperature environment may be made using a chamber 6 in a region where the cryogenic impact is performed, as illustrated in FIG. 2.

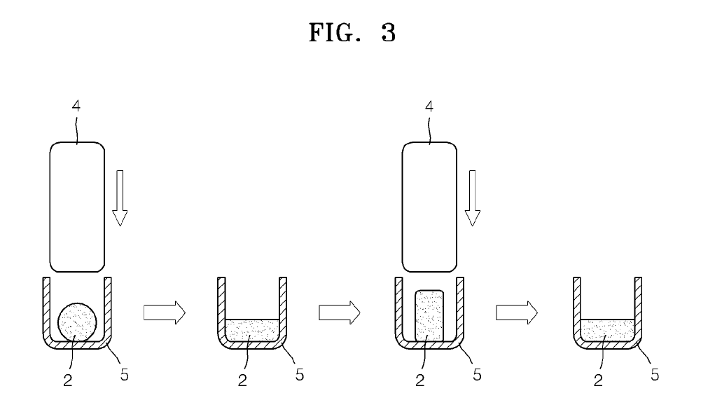

The cryogenic impact 4 is performed in the chamber 6, and is performed in such a manner that an impact is applied to the jacket 1 mounted on the support 5 at a high strain rate using a hammer. The cryogenic impact 4 may be performed once or repeatedly performed two or more times as illustrated in FIG. 3. That is, with reference now to the FIGS. 1 and 3, in a single-step impact, an impact is applied once to the jacket 1, and, in a multi-step impact, an impact is applied to the jacket 1, the position of the jacket 1 in the chamber 6 is then changed, and impact is applied thereto again. In the multi-step impact, the impact is uniformly applied to the jacket 1.

In a process prior to the cryogenic impact, preheat treatment may be performed on the thermoelectric material to have a crystalline orientation. Enhancing crystalline orientation results in an enhanced figure of merit ZT. The preheat treatment process is performed by induction heating, laser heating, flame heating, or furnace heating, and heat is applied to the jacket through the preheat treatment process, thereby increasing the temperature of the thermoelectric material.

Prior to the cryogenic impact and preheat treatment, the jacket 1 may be subjected to single-axis deformation. The single-axis deformation may be performed at room temperature or at a temperature in the range of about 100° C. to about 600° C. as illustrated in FIGS. 2 and 3. The particles of the thermoelectric material may be elongated in one direction by rolling, swaging, pultrusion or extrusion by using a roller 3, thereby having a flattened anisotropic microstructure.

The thermoelectric material powder may have a more flattened linear structure by the single-axis deformation. As a result, the density of state increases, and the Seebeck Coefficient S and the electrical conductivity a become much higher due to the further increased density of state. In addition, if the dimension involved is less than the phonon wavelength, the thermal conductivity k becomes smaller.

Contents related to the single-axis deformation are disclosed in WO 2010/018976, the contents of which are incorporated herein in their entirety.

The single-axis deformation, preheat treatment process and cryogenic impact may be consecutively performed. These processes may be separately performed, however, may be consecutively performed to increase manufacturing efficiencies.

A detailed description of the type of thermoelectric material used in the manufacturing process is already provided above.

According to another embodiment, there is provided a thermoelectric device including the thermoelectric material.

The thermoelectric device may be manufactured in bulk form by mechanically or chemically mixing the thermoelectric material with defects and partially reducing and heat treating the resultant, or by performing on the thermoelectric material subsequent processes such as melting followed by quenching and sintering the resultant in pressure. Spark plasma sintering (SPS) may be used as the sintering process. The SPS process enables rapid sintering at a relatively low temperature as compared to a typical sintering process, and thus the original structure of thermoelectric semiconductor particles and nanosheets is not exposed to a high temperature during the sintering process. As a result, the properties of the initial raw material may be maintained. In addition, the SPS process provides real-time removal of a surface oxide layer, and thus a thermoelectric device with high intensity and uniform characteristics may be manufactured.

The thermoelectric device may be manufactured in a predetermined form such as a rectangular shape by cutting, thereby rendering it in a form capable of being used in a thermoelectric module. The thermoelectric device may be a p-type or n-type thermoelectric device. The thermoelectric device comprises electrodes, and may be a device that has cooling effects due to the application of an electrical current, or a device that has power generation effects due to a temperature difference.

According to another embodiment, there is provided a thermoelectric module including a first electrode; a second electrode facing the first electrode; and a thermoelectric device disposed between the first electrode and the second electrode.

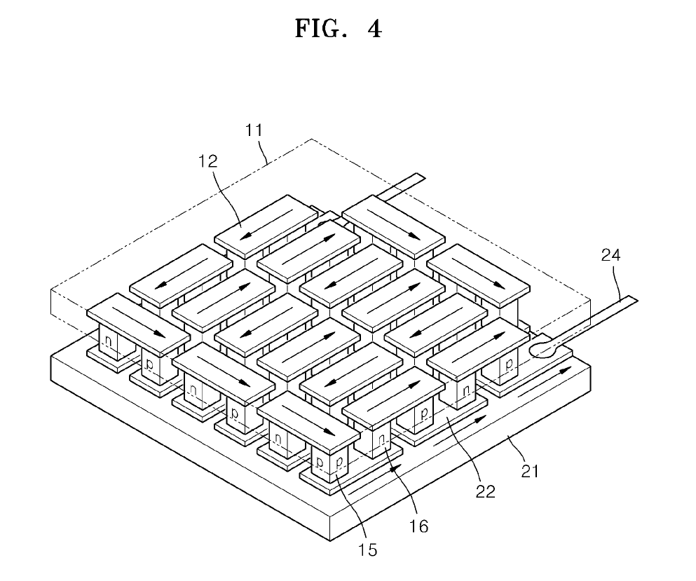

FIG. 4 is a diagram of a thermoelectric module including the thermoelectric device described above, according to an embodiment. Referring to FIG. 4, upper electrodes 12 and lower electrodes 22 are respectively patterned on an upper electrically insulating substrate 11 and a lower electrically insulating substrate 21. P-type thermoelectric elements 15 and n-type thermoelectric elements 16 contact the upper electrodes 12 and the lower electrodes 22. The upper and lower electrodes 12 and 22 are externally connected to the thermoelectric device via a lead electrode 24.

The upper and lower electrically insulating substrates 11 and 21 may be formed of gallium arsenide (GaAs), sapphire, silicon, pyrex or quartz. The upper and lower electrodes 12 and 22 may be formed of aluminum, nickel, gold or titanium, and the sizes thereof may be variously selected. The patterning of the upper and lower electrodes 12 and 22 may be performed using a well-known patterning method in the art, for example, lift-off semiconductor processing, deposition or photolithography. The thermoelectric elements 15 and 16 comprise the cryogenic impact modified thermoelectric material.

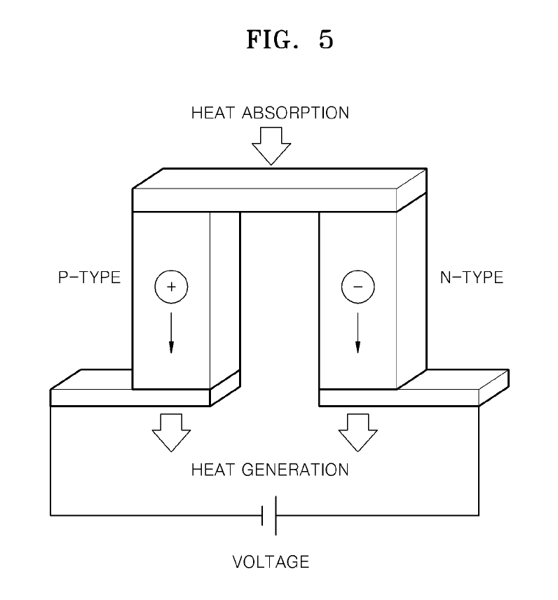

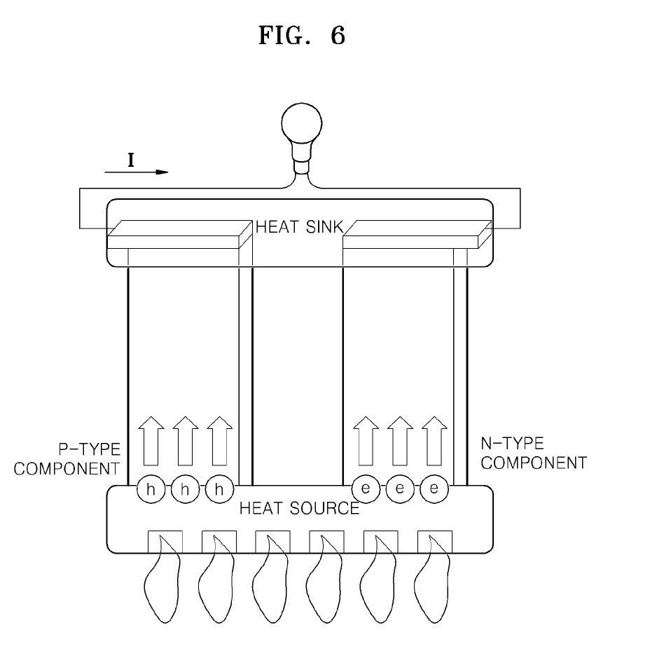

According to an embodiment, illustrated in FIGS. 5 and 6, the thermoelectric module includes a first electrode, a second electrode, and the thermoelectric device described above disposed between the first electrode and the second electrode. The thermoelectric module may further include an insulating substrate on which at least one of the first electrode and the second electrode is disposed. A detailed description of the type of the insulating substrate is already provided above.

The first electrode and the second electrode may be, as illustrated in FIG. 5, electrically connected to a power source. When a DC voltage is externally applied to the first and second electrodes, holes of a p-type thermoelectric device and electrons of an n-type thermoelectric device are transferred, and thus heat generation/absorption may occur at both ends of the thermoelectric device.

At least one of the first electrode and the second electrode may be, as illustrated in the FIG. 6, exposed to a heat source. When heat is externally supplied to the thermoelectric device by the heat source, electrons and holes of the thermoelectric device are transferred, and thus the flow of current occurs therein, resulting in generation of electricity.

The p-type thermoelectric device and the n-type thermoelectric device may be alternately arranged with respect to each other, and at least one of the p-type thermoelectric device and the n-type thermoelectric device may include a nanosheet-containing thermoelectric material.

According to another embodiment, there is provided a thermoelectric apparatus including a heat source and the thermoelectric module. The thermoelectric module absorbs heat from the heat source, and includes a thermoelectric material that includes a coating layer, a first electrode and a second electrode facing the first electrode. Either the first electrode or the second electrode may contact the thermoelectric material.

The thermoelectric apparatus may further include a power source that is electrically connected to the first electrode and the second electrode. The thermoelectric apparatus may further include an electric device that is electrically connected to either the first electrode or the second electrode.

The thermoelectric apparatus may be a thermoelectric cooling system or a thermoelectric power generation system. Examples of the thermoelectric cooling system may include, but are not limited to, a micro cooling system, a commonly-used cooling device, an air handing unit, and a waste heat power generation system. The configuration and manufacturing method of the thermoelectric cooling system are well known in the art, and thus a detailed description thereof is not provided herein.

One or more embodiments will now be described in further detail with reference to the following examples. These examples are for illustrative purposes only and are not intended to limit the scope of the embodiments.

### Example 1

A copper jacket having a diameter of 0.375 inch was filled with Bi_{0.5}Sb_{1.5}Te₃ thermoelectric material powder having an average particle size of about 25 micrometers (“μm”), and both ends of the copper jacket were sealed by swaging method using a die having a smaller diameter than that of the copper jacket. The copper jacket including the thermoelectric material was subjected to swaging using a swage, thereby reducing the diameter of the copper jacket to 0.08 inch.

Subsequently, an impact was applied to the jacket using a Hopkinson bar impact device at a strain rate of 2,000 inch/inch/sec, thereby inducing defects in the thermoelectric material powder.

As a result the microstructure of the thermoelectric material had a defect density that was about 6 times greater than that before the impact deformation (increased from 125 mm²/1 mm³ to 700 mm²/1 mm³).

The Seebeck coefficient of the thermoelectric material was measured to be S=+199 μV/K using a 4-terminal method.

The electrical conductivity of the thermoelectric material was measured to be σ=1.034×10⁵ μV/K at 300K using a 4-terminal method.

The thermal conductivity of the thermoelectric material was measured to be k=0.824 W/mK at 300K using a 3-omega method. In contrast, in the case of Bi_{0.5}Sb_{1.5}Te₃ thermoelectric material powder subjected only to a hot press process without cryogenic impact or single-axis deformation, the thermal conductivity of the thermoelectric material was measured to be k=1.100 W/mK at 300K.

Consequently, the figure of merit ZT of the thermoelectric material was estimated to be about 1.47, and this is a substantial improvement of about 50% as compared to the known ZT value of ideal thermoelectric material alloy, i.e., about 0.95 to about 1.05.

As described above, according to the one or more of the above embodiments of the present invention, a thermoelectric material is deformed by cryogenic impact, and thus the defect density of a microstructure thereof is increased and the thermoelectric material has a flattened anisotropic microstructure, which results in enhanced figure of merit of the thermoelectric material. Therefore, a thermoelectric device, a thermoelectric module or a thermoelectric apparatus including the thermoelectric material described above exhibits enhanced efficiency.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A thermoelectric material having a microstructure deformed by cryogenic impact.

2. The thermoelectric material of claim 1, wherein the cryogenic impact is performed at a strain rate of about 5 inch/inch/sec or greater.

3. The thermoelectric material of claim 1, wherein the cryogenic impact is performed at a strain rate in the range of about 50 inch/inch/sec to about 2,000 inch/inch/sec.

4. The thermoelectric material of claim 1, wherein a defect density of the thermoelectric material is at least about 2 times greater than that before the cryogenic impact.

5. The thermoelectric material of claim 1, wherein a defect density of the thermoelectric material is about 5 times greater than that before the cryogenic impact.

6. The thermoelectric material of claim 1, wherein the microstructure is an anisotropically elongated and flattened microstructure.

7. The thermoelectric material of claim 1, wherein the cryogenic impact is performed at below about 0° C.

8. The thermoelectric material of claim 1, wherein the cryogenic impact is performed at below about −50° C.

9. The thermoelectric material of claim 1, wherein the cryogenic impact is performed at below about −100° C.

10. The thermoelectric material of claim 1, comprising at least one element selected from the group consisting of a transition metal, a rare earth element, a Group II element, a Group XIII element, a Group XIV element, a Group XV element, and a Group XVI element.

11. The thermoelectric material of claim 1, comprising at least one thermoelectric material selected from the group consisting of Si, Bi—Sb—Te, Bi—Te—Se, Bi—Sb, Mg—Si, Mg—Ge, Mg—Sn, Pb—Sb—Ag—Te, B—C, Bi—Te, Co—Sb, Pb—Te, Ge—Tb, Si—Ge, Sb—Te, Sm—Co, and transition metal silicides.

12. The thermoelectric material of claim 1, comprising at least one thermoelectric material selected from the group consisting of Si, Si₁₋ₓGeₓ where 0<x<1, Bi₂Te₃, Sb₂Te₃, BiₓSb₂₋ₓTe₃ where 0<x<2, Bi₂TeₓSe₃₋ₓ where 0<x<3, B₄C/B₉C, BiSb alloy, PbTe, Mg—Si, Mg—Ge, Mg—Sn or ternary systems, binary/tertiary/quaternary skutterudites, and Pb—Sb—Ag—Te.

13. The thermoelectric material of claim 1, wherein a figure of merit of the thermoelectric material after the cryogenic impact is about 20% greater than that before the cryogenic impact; wherein the figure of merit is represented by ZT in the equation <1> below:
$$ZT = \frac{{S}^{2} σ T}{k} \qquad 〈 Equation 1 〉$$
wherein S is the Seebeck Coefficient (in Volts/degree K), a is the electrical conductivity (in 1/Ω-meter), T refers to absolute temperature in degrees Kelvin (K), and k is the thermal conductivity (in Watt/meter-degree K).

14. The thermoelectric material of claim 13, wherein a figure of merit of the thermoelectric material after the cryogenic impact is about 30% greater than that before the cryogenic impact.

15. A method of preparing a thermoelectric material, the method comprising:
preparing thermoelectric material powder;
introducing the thermoelectric material powder into a metal jacket;
packing and sealing the metal jacket; and
applying cryogenic impact to the metal jacket comprising the thermoelectric material powder to deform a microstructure of the thermoelectric material powder.

16. The method of claim 15, wherein the cryogenic impact is performed at below about 0° C.

17. The method of claim 15, further comprising, before the cryogenic impact, applying single-axis deformation to the metal jacket comprising the thermoelectric material powder to reduce the diameter of the metal jacket and elongating the metal jacket to obtain a rod-type metal jacket.

18. The method of claim 17, wherein the single-axis deformation is performed at room temperature or at a temperature in the range of about 100° C. to about 600° C.

19. The method of claim 17, further comprising performing preheat treatment between the cryogenic impact and the single-axis deformation.

20. A thermoelectric device comprising the thermoelectric material according to claim 1.

21. A thermoelectric module comprising:
a first electrode;
a second electrode facing the first electrode; and
the thermoelectric device of claim 20 disposed between the first electrode and the second electrode.

22. A thermoelectric apparatus comprising:
a heat source; and
a thermoelectric module comprising:
the thermoelectric device of claim 20 absorbing heat from the heat source;
a first electrode contacting the thermoelectric device; and
a second electrode facing the first electrode and contacting the thermoelectric device.
